(19) United States
(12) Patent Application Publication
(10) Pub. No.: US 2011/0121264 A1
(43) Pub. Date: May 26, 2011

(54) COMPOSITE STRUCTURE OF GRAPHENE AND NANOSTRUCTURE AND METHOD OF MANUFACTURING THE SAME

(75) Inventors: Byoung-lyong CHOI, Seoul (KR); Eun-kyung LEE, Seoul (KR); Dong-mok WHANG, Suwon-si (KR); Byung-sung KIM, Suwon-si (KR)

(73) Assignee: SAMSUNG ELECTRONICS CO., LTD., Suwon-si (KR)

(21) Appl. No.: 12/765,930

(22) Filed: Apr. 23, 2010

(30) Foreign Application Priority Data
Nov. 25, 2009 (KR) 10-2009-0114637

(51) Int. Cl. H01L 29/15; H01B 1/04; H01L 21/20

(52) U.S. Cl. 257/14; 252/502; 438/478; 977/700; 977/742; 977/762; 257/E29.072; 257/E21.09

(57) ABSTRACT

A composite structure includes; graphene and at least one substantially one-dimensional nanostructure disposed on the graphene.

### CROSS-REFERENCE TO RELATED APPLICATION

This application claims priority to Korean Patent Application No. 10-2009-0114637, filed on Nov. 25, 2009, and all the benefits accruing therefrom under 35 U.S.C. §119, the content of which in its entirety is herein incorporated by reference.

### BACKGROUND

1. Field

The present disclosure relates to composite structures of graphene molecules and nanostructures, and more particularly, to composite structures including two-dimensional graphene molecules and one-dimensional nanostructures, and methods of manufacturing the composite structures.

2. Description of the Related Art

Carbon nanotubes have been a subject of study since the early 1990s but recently, planar graphenes have been objects of increasingly interest. Graphene is a thin film material having a thickness of several nm in which carbon atoms are aligned two-dimensionally, and charges, e.g., charge carrying particles, act as zero effective mass particles therein, and thus have a very high electrical conductivity and also a very high thermal conductivity and elasticity. Accordingly, research is being conducted into the various characteristics of graphene and its various application fields. Graphene is appropriate for applications in transparent and flexible devices due to its high electrical conductivity and elasticity.

### SUMMARY

Provided are composite structures including two-dimensional graphenes and one-dimensional nanostructures, and methods of manufacturing the composite structures.

Additional aspects will be set forth in part in the description which follows and, in part, will be apparent from the description, or may be learned by practice of the presented embodiments.

According to an aspect of the present disclosure, a composite structure includes; graphene, and at least one substantially one-dimensional nanostructure disposed on the graphene.

In one embodiment, the at least one nanostructure may be electrically connected to the graphene, and one of disposed substantially perpendicularly to and inclined with respect to the graphene.

In one embodiment, the at least one nanostructure is selected from the group consisting of nanowires, nanotubes, nanorods and combinations thereof.

In one embodiment, the at least one nanostructure may include a material selected from the group consisting of a IV group semiconductor, a III-V group semiconductor, a II-VI semiconductor, a IV-VI semiconductor, a IV-V-VI semiconductor, an oxide semiconductor, a nitride semiconductor, a metal and a combination thereof.

In one embodiment, the at least one nanostructure may have at least one of a heterostructure in a radius direction and a heterostructure in a length direction. In one embodiment, the at least one nanostructure may be doped with a conductive impurity.

In one embodiment, the composite structure may further include a substrate on which the graphene is disposed.

According to an aspect of the present disclosure, a composite structure includes; a first graphene, a second graphene separated apart from the first graphene, and at least one substantially one-dimensional nanostructure disposed between the first graphene and the second graphene.

In one embodiment, the at least one graphene may be electrically connected to the first graphene and the second graphene and may be one of disposed substantially perpendicularly to and inclined with respect to the first graphene and the second graphene. In one embodiment, an insulating material may be filled between the first graphene and the second graphene in spaces left between the at least one nanostructure.

According to an aspect of the present disclosure, a method of manufacturing a composite structure includes; providing a substrate; disposing graphene on the substrate, and growing at least one substantially one-dimensional nanostructure on the graphene.

In one embodiment, the at least one nanostructure may be grown from the substrate. In one embodiment, the method may further include surface-treating the substrate prior to growing the at least one nanostructure on the graphene.

In one embodiment, the method may further include forming a catalyst metal layer on the graphene after disposing the graphene on the substrate. In one embodiment, the at least one nanostructure may be grown from the catalyst metal layer.

### BRIEF DESCRIPTION OF THE DRAWINGS

These and/or other aspects will become apparent and more readily appreciated from the following description of the embodiments, taken in conjunction with the accompanying drawings of which:

FIG. 1 is a front perspective view illustrating an embodiment of a composite structure of graphene and a nanostructure;

FIG. 2 is another embodiment of the nanostructure of FIG. 1;

FIG. 3 is another embodiment of the nanostructure of FIG. 1;

FIG. 4 is a front perspective view illustrating another embodiment of a composite structure of graphene and a nanostructure;

FIG. 5 is a front perspective view illustrating another embodiment of a composite structure of graphene and a nanostructure;

FIGS. 6 through 8 are schematic views illustrating an embodiment of a method of manufacturing another embodiment of a composite structure of graphene and a nanostructure; and

FIGS. 9 and 10 are schematic views illustrating an embodiment of a method of manufacturing another embodiment of a composite structure of graphene and a nanostructure.

### DETAILED DESCRIPTION

Embodiments now will be described more fully hereinafter with reference to the accompanying drawings, in which embodiments are shown. These embodiments may, however, be embodied in many different forms and should not be construed as limited to the embodiments set forth herein. Rather, these embodiments are provided so that this disclosure will be thorough and complete, and will fully convey the scope of the disclosure to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the disclosure.

All methods described herein can be performed in a suitable order unless otherwise indicated herein or otherwise clearly contradicted by context. The use of any and all examples, or exemplary language (e.g., “such as”), is intended merely to better illustrate the disclosure and does not pose a limitation on the scope thereof unless otherwise claimed. No language in the specification should be construed as indicating any non-claimed element as essential to the practice of the embodiments as used herein.

Hereinafter, the embodiments will be described in detail with reference to the accompanying drawings.

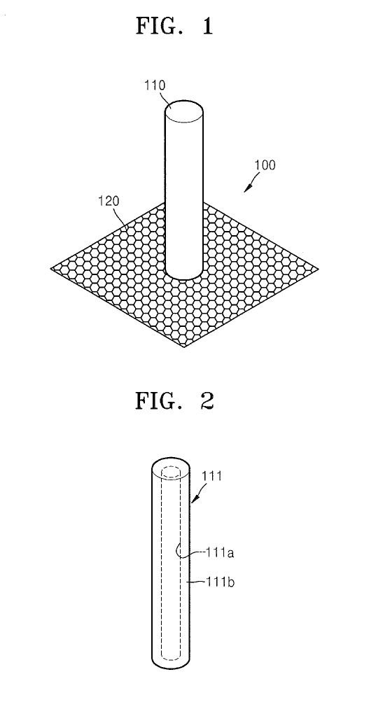

FIG. 1 is a perspective view illustrating an embodiment of a composite structure 100 of graphene and a nanostructure.

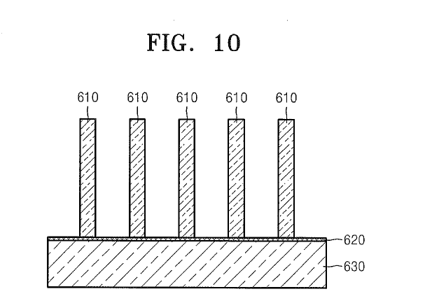

Referring to FIG. 1, the composite structure 100 includes graphene 120 and a nanostructure 110 disposed on the graphene 120. In one embodiment, the nanostructure 110 may be formed on the graphene 120. The graphene 120 is a thin film material having a thickness of several nanometers (nm), in which carbon atoms are aligned two-dimensionally, and has a planar structure. In the graphene 120, charges, e.g., charge carrying particles, act as zero effective mass particles, and thus the graphene 120 has a very high electrical conductivity, high elasticity, and high thermal conductivity. The graphene 120 may also be disposed on a substrate as will be described in more detail later (see FIG. 8 and FIG. 10).

The nanostructure 110 formed on the graphene 120 has essentially a one-dimensional shape, and may be, for example, a nanowire, a nanorod, or a nanotube. As used herein, the term one-dimensional is used to describe a component which is much longer in one dimension than any other dimension, e.g., the nanostructure 110 illustrated in FIG. 1 has a structure which has a length which is orders of magnitude larger than its radius. The one-dimensional nanostructure 110 is formed to be electrically connected to the graphene 120, and may be disposed substantially perpendicularly to the graphene 120 or be inclined at a predetermined angle with respect to the graphene 120. The one-dimensional nanostructure 110 may be formed of various materials. For example, embodiments of the nanostructure 110 may be formed of a IV group semiconductor such as C, Si, Ge or other materials with similar characteristics, a III-V group semiconductor, a II-VI semiconductor, a IV-VI semiconductor, or a IV-V-VI semiconductor, or an oxide semiconductor such as ZnO, a nitride semiconductor, or a metal or other materials with similar characteristics but the one-dimensional nanostructure 110 is not limited thereto and may be formed of any of a variety of other materials. Meanwhile, the nanostructure 110 may have a heterostructure in which materials having different components are combined with each other, for example, a heterostructure in a radius direction thereof or a heterostructure in a length direction thereof.

FIG. 2 illustrates another example embodiment of the nanostructure 110 of FIG. 1. In FIG. 2, a nanostructure 111 having a heterostructure in a radius direction is illustrated. Referring to FIG. 2, the nanostructure 111 includes a core portion 111a and a shell portion 111b (which may also be referred to as a cladding portion) that is formed to surround the core portion 111a. The core portion 111a and the shell portion 111b may be formed of, for example, a IV group semiconductor, a III-V group semiconductor, a II-VI semiconductor, a IV-VI semiconductor, or a IV-V-VI semiconductor, an oxide semiconductor, a nitride semiconductor, or a metal or other materials with similar characteristics, but the core portion 111a and the shell portion 111b are not limited thereto and may be formed of any of a variety of other materials. In one embodiment, the core portion 111a and the shell portion 111b may be doped with conductive impurities including, for example, p-type or n-type materials.

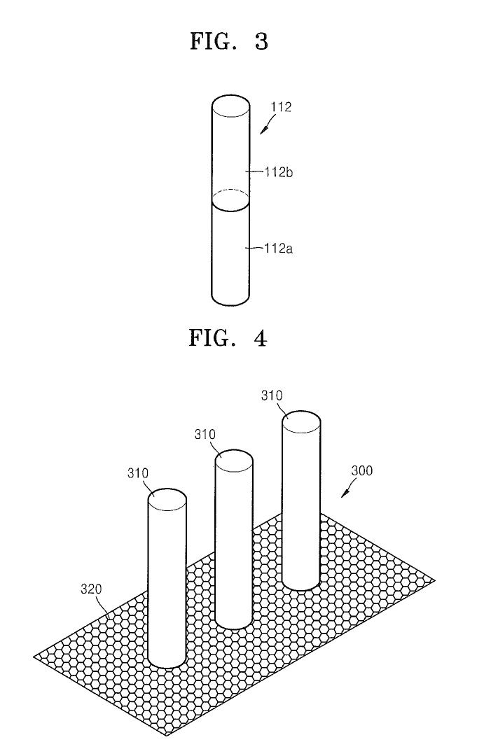

FIG. 3 illustrates another example of the nanostructure 110 of FIG. 1. In FIG. 3, a nanostructure 112 having a heterostructure in a length direction is illustrated. Referring to FIG. 3, the nanostructure 112 includes first and second nanostructures 112a and 112b which are both linear in structure. As described above, the first and second nanostructures 112a and 112b may be formed of, for example, a IV group semiconductor, a III-V group semiconductor, a II-VI semiconductor, a IV-VI semiconductor, or a IV-V-VI semiconductor, an oxide semiconductor, a nitride semiconductor, or a metal or other materials with similar characteristics. In one embodiment, the first and second nanostructures 112a and 112b may be doped with conductive impurities including, for example, p-type or n-type materials.

The composite structure 100 according to the current embodiment includes the graphene 120 which is substantially two-dimensional and the nanostructure 100 which is substantially one-dimensional and disposed on the graphene 120. In the composite structure 100, charges that are transferred through the graphene 120 which has a high electrical conductivity may move along the one-dimensional nanostructure 110 or charges that are transferred through the nanostructure 110 may quickly move through the graphene 120. Accordingly, the composite structure 100 of the graphene 120 and the nanostructure 110 may be used in various fields such as a logic device, a memory device, a supercapacitor, a sensor, an optical device, an energy storage device, a transparent display device, or other similar applications. Also, the composite structure 100 that is manufactured by combining the graphene 120, which is flexible and has high electrical conductivity and elasticity, and the nanostructure 110 such as a nanowire may be applied to implement a flexible and stretchable device.

FIG. 4 is a front perspective view illustrating another embodiment of a composite structure 300 of graphene and a nanostructure.

Referring to FIG. 4, the composite structure 300 includes graphene 320 and a plurality of nanostructures 310 that are formed on the graphene 320. In FIG. 4, three nanostructures 310 are formed on the graphene 320, but the present embodiment is not limited thereto. Alternative embodiments include configurations wherein two or four or more nanostructures 310 may be formed on the graphene 320. The nanostructures 310 are substantially one-dimensional, and may be, for example, nanowires, nanorods, or nanotubes. The nanostructures 310 are formed to be electrically connected to the graphene 320, and may be disposed substantially perpendicularly to the graphene 320 or be inclined at a predetermined angle to the graphene 320.

As described above, the nanostructures 310 may be formed of a IV group semiconductor, a III-V group semiconductor, a II-VI semiconductor, a IV-VI semiconductor, or a IV-V-VI semiconductor, or an oxide semiconductor such as ZnO, a nitride semiconductor, or a metal or other materials with similar characteristics, but are not limited thereto and may be formed of any of other a variety of different materials. Meanwhile, the nanostructures 310 may have a heterostructure in which materials having different components are combined with each other, for example, a heterostructure in a radius direction or a heterostructure in a length direction, embodiments of which are described above with respect to FIGS. 2 and 3. In this case, the nanostructures 310 may be doped with conductive impurities.

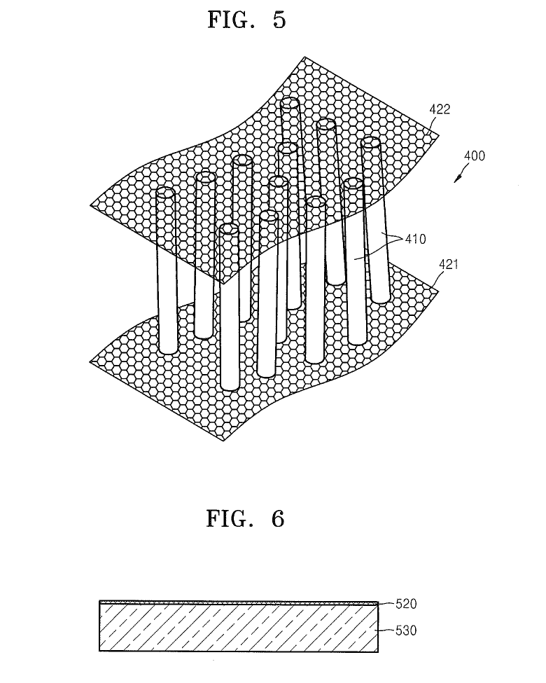

FIG. 5 is a perspective view illustrating another embodiment of a composite structure 400 of graphene and a nanostructure.

Referring to FIG. 5, the composite structure 400 according to the current embodiment includes first and second graphenes 421 and 422 that are disposed separately from each other and a plurality of nanostructures 410 that are disposed between the first and second graphenes 421 and 422. Meanwhile, alternative embodiments include configurations wherein the number of the nanostructures 410 formed between the first and second graphenes 421 and 422 may be varied, and additional embodiments include configurations where only one nanostructure 410 may be formed between the first and second graphenes 421 and 422.

The nanostructures 410 are substantially one-dimensional, and may be, for example, nanowires, nanorods, or nanotubes. The nanostructures 410 are formed to be electrically connected to the first and second graphenes 421 and 422, and may be disposed substantially perpendicularly to the first and second graphenes 421 and 422 or may be disposed at an inclined angle thereto. The nanostructures 410 may be disposed separately from one another and in one embodiment a filling material (not shown) such as an insulation material may be filled between the nanostructures 410. Alternative embodiments include configurations wherein the filling material may be omitted.

As described above, the nanostructures 410 may be formed of a IV group semiconductor, a III-V group semiconductor, a II-VI semiconductor, a IV-VI semiconductor, or a IV-V-VI semiconductor, or an oxide semiconductor such as ZnO, a nitride semiconductor, or a metal or other materials with similar characteristics but the nanostructures 410 are not limited thereto and may be formed of any of a variety of other materials. Meanwhile, the nanostructures 410 may have a heterostructure in which materials having different components are combined to each other, for example, a heterostructure in a radius direction or a heterostructure in a length direction embodiments of which are described above with respect to FIGS. 2 and 3. In this case, the nanostructures 410 may be doped with conductive impurities.

In the composite structure 400 according to the current embodiment, the first and second graphenes 421 and 422 are disposed between two ends of the at least one nanostructure 410. The composite structure 400 may be applied as a flexible and stretchable transparent device in various fields.

FIGS. 6 through 8 are schematic views illustrating an embodiment of a method of manufacturing another embodiment of a composite structure of graphene and a nanostructure.

Referring to FIG. 6, first, a substrate 530 is provided. The substrate 530 may be, for example, a silicon substrate, a glass substrate or a substrate made from other materials with similar characteristics, but is not limited thereto and may be formed of various materials. Graphene 520 is formed on an upper surface of the substrate 530. The graphene 520 is a thin film material having a thickness of only several nm, in which carbon atoms are arranged two-dimensionally, and has a planar structure.

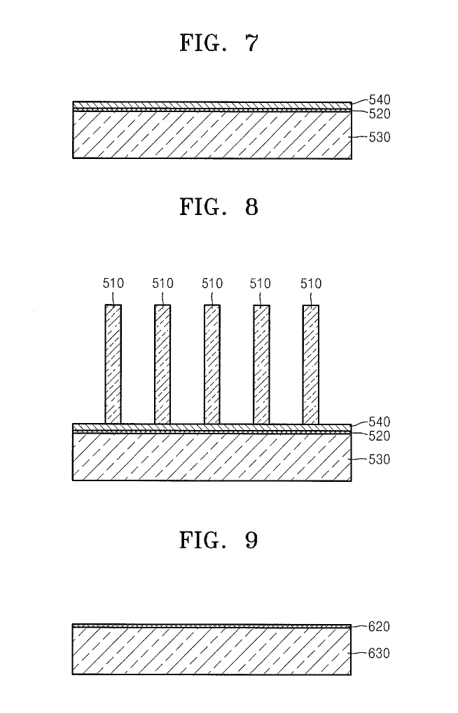

Referring to FIG. 7, a metal catalyst layer 540 is formed on the graphene 520. The metal catalyst layer 540 functions as a seed layer for growing substantially one-dimensional nanostructures 510, the process of which will be described later. Accordingly, a material of which the metal catalyst layer 540 is composed is determined by a material of the nanostructures 510 are ultimately to be composed of. Meanwhile, after forming the metal catalyst layer 540, patterning of the metal catalyst layer 540 may be further performed. Thus, by patterning the metal catalyst layer 540, density and sizes of the nanostructures 510 to be grown may be adjusted accordingly.

Referring to FIG. 8, substantially one-dimensional nanostructures 510 are grown from the metal catalyst layer 540. Embodiments of the nanostructures 510 may be nanowires, nanotubes, or nanorods as described above. The nanostructures 510 may be grown using a dry process such as a chemical vapor deposition (“CVD”) method or a wet process in which the nanostructures 510 are grown in a predetermined solution or various other similar methods. By using the above-described growth process, the substantially one-dimensional nanostructures 510 having a substantially one-dimensional shape are formed on the graphene 520, thereby forming a composite structure of the graphene 520 and the nanostructures 510. The one-dimensional nanostructures 510 may be disposed substantially perpendicularly to the substrate 530 or may be inclined at a predetermined angle to the substrate 530. The number of the nanostructures 510 that are grown from the metal catalyst layer 540 may be varied. In one embodiment, the metal catalyst layer 540 is completely incorporated into the nanostructures 510, thereby leaving no metal catalyst layer 540 on the graphene 520, in another embodiment, the metal catalyst layer 540 that is not incorporated into the nanostructure 510 may be removed by a subsequent processing step.

In on embodiment the nanostructures 510 may be formed of a IV group semiconductor such as C, Si, Ge, a III-V group semiconductor, a II-VI semiconductor, a IV-VI semiconductor, or a IV-V-VI semiconductor, or an oxide semiconductor such as ZnO, a nitride semiconductor, or a metal or other materials with similar characteristics but are not limited thereto and may be formed of any of a variety of other materials. Meanwhile, the nanostructures 510 may have not only a homogeneous structure formed of the same material but also a heterostructure in which materials having different components are combined with each other. For example, in one embodiment the nanostructures 510 may have a heterostructure in a radius direction or a heterostructure in a length direction as described above with respect to FIGS. 2 and 3. As described above, the nanostructures 510 having a heterostructure may be formed of a IV group semiconductor, a III-V group semiconductor, a II-VI semiconductor, a IV-VI semiconductor, or a IV-V-VI semiconductor, or an oxide semiconductor, a nitride semiconductor, or a metal or other materials with similar characteristics. In this case, the nanostructures 510 may be doped with conductive impurities.

Meanwhile, the substrate 530 may be removed from a resultant material illustrated in FIG. 8 in a subsequent process. However, the composite structure may also be formed without removing the substrate 530. Then, by attaching graphene (not shown) on surfaces of upper ends of the nanostructures 510, the composite structure 400 formed of the first and second graphenes 421 and 422 and nanostructures 410 illustrated in FIG. 5 may be formed.

FIGS. 9 and 10 are schematic views illustrating another embodiment of a method of manufacturing a composite structure of graphene and a nanostructure.

Referring to FIG. 9, first, a substrate 630 is formed. The substrate 630 may be, for example, a silicon substrate, a germanium substrate, a glass substrate, a plastic substrate or a substrate made from other materials with similar characteristics. However, the substrate 630 is not limited thereto. Surface treatment of the substrate 630 may be further performed. As a result of the surface treatment, a seed layer (not shown) for growing nanostructures 610 which will be described later may be formed on an upper surface of the substrate 630. For example, when the substrate 630 is a silicon substrate, a seed layer for forming a silicon nanostructure may be formed on the upper surface of the substrate 630 via a surface treatment of the substrate 630. When the substrate 630 is a germanium substrate, a seed layer for forming a germanium nanostructure may be formed on the upper surface of the substrate 630 via a surface treatment of the substrate 630. Meanwhile, a nanostructure may also be formed without surface-treating the substrate 630. For example, when the substrate 630 is a glass substrate, a plastic substrate, or a substrate made from another material with similar characteristics, for example, a ZnO nanostructure may be grown on the substrate 630 without surface-treating the substrate 630. Subsequently, graphene 620 is formed on the upper surface of the substrate 630.

Referring to FIG. 10, one-dimensional nanostructures 610 are grown from the substrate 630. Embodiments of the nanostructures 610 may include nanowires, nanotubes, or nanorods. Growing of the nanostructures 610 may be performed using a dry process, a wet process or other similar processes as described above. Substantially one-dimensional nanostructures 610 are formed on the graphene 620 via the growth process, thereby completing a composite structure of the graphene 620 and the nanostructures 610. The nanostructures 610 may be disposed substantially perpendicularly to the substrate 630 or be inclined at a predetermined angle to the substrate 630. A number of the nanostructures 610 grown from the substrate 630 may be varied.

As described above, the nanostructures 610 may be formed of a IV group semiconductor, a III-V group semiconductor, a II-VI semiconductor, a IV-VI semiconductor, or a IV-V-VI semiconductor, or an oxide semiconductor such as ZnO, a nitride semiconductor, or a metal or other materials with similar characteristics but are not limited thereto and may be formed of any of other various materials. Meanwhile, the nanostructures 610 may have a heterostructure in which materials having different components are combined to each other, for example, a heterostructure in a radius direction or a heterostructure in a length direction as described above in detail with respect to FIGS. 2 and 3. In this case, the nanostructures 610 may be doped with conductive impurities.

Meanwhile, in subsequent processes, the substrate 630 may be removed from a resultant material illustrated in FIG. 10. However, a composite structure may also be formed without removing the substrate 630. Also, by attaching graphene (not shown) on surfaces of upper ends of the nanostructures 610 illustrated in FIG. 10, the composite structure 400 formed of the first and second graphenes 421 and 422 and the nanostructures 410 illustrated in FIG. 5 may be formed.

It should be understood that the exemplary embodiments described therein should be considered in a descriptive sense only and not for purposes of limitation. Descriptions of features or aspects within each embodiment should typically be considered as available for other similar features or aspects in other embodiments.

What is claimed is:

1. A composite structure comprising:
graphene; and
at least one substantially one-dimensional nanostructure disposed on the graphene.

2. The composite structure of claim 1, wherein the at least one nanostructure is electrically connected to the graphene, and is one of disposed substantially perpendicularly to and disposed inclined with respect to the graphene.

3. The composite structure of claim 1, wherein the at least one nanostructure is selected from the group consisting of nanowires, nanotubes, nanorods and combinations thereof.

4. The composite structure of claim 1, wherein the at least one nanostructure comprises a material selected from the group consisting of a IV group semiconductor, a III-V group semiconductor, a II-VI semiconductor, a IV-VI semiconductor, a IV-V-VI semiconductor, an oxide semiconductor, a nitride semiconductor, a metal and combinations thereof.

5. The composite structure of claim 1, wherein the at least one nanostructure has one of a heterostructure in a radius direction and a heterostructure in a length direction.

6. The composite structure of claim 5, wherein the at least one nanostructure comprises a material selected from the group consisting of a IV group semiconductor, a III-V group semiconductor, a II-VI semiconductor, a IV-VI semiconductor, a IV-V-VI semiconductor, an oxide semiconductor, a nitride semiconductor, a metal and combinations thereof.

7. The composite structure of claim 5, wherein the at least one nanostructure is doped with a conductive impurity.

8. The composite structure of claim 1, further comprising a substrate on which the graphene is disposed.

9. A composite structure comprising:
a first graphene; and
a second graphene separated apart from the first graphene; and
at least one substantially one-dimensional nanostructure disposed between the first graphene and the second graphene.

10. The composite structure of claim 9, wherein the at least one nanostructure is electrically connected to the first graphene and the second graphene and is one of disposed substantially perpendicularly to and inclined with respect to the first graphene and the second graphene.

11. The composite structure of claim 9, wherein an insulating material is filled between the first graphene and the second graphene in spaces left between the at least one nanostructure.

12. The composite structure of claim 9, wherein the nanostructure comprises a material selected from the group consisting of a IV group semiconductor, a III-V group semiconductor, a II-VI semiconductor, a IV-VI semiconductor, a IV-V-VI semiconductor, an oxide semiconductor, a nitride semiconductor, a metal and combinations thereof.

13. The composite structure of claim 9, wherein the at least one nanostructure has at least one of a heterostructure in a radius direction and a heterostructure in a length direction.

14. The composite structure of claim 13, wherein the at least one nanostructure is doped with a conductive impurity.

15. A method of manufacturing a composite structure, the method comprising:
providing a substrate;
disposing graphene on the substrate; and
growing at least one substantially one-dimensional nanostructure on the graphene.

16. The method of claim 15, wherein the at least one nanostructure is one of disposed substantially perpendicularly to and inclined with respect to the substrate.

17. The method of claim 15, wherein the at least one nanostructure is grown from the substrate.

18. The method of claim 15, further comprising surface-treating the substrate prior to growing the at least one nanostructure on the graphene.

19. The method of claim 15, further comprising forming a catalyst metal layer on the graphene after disposing the graphene on the substrate.

20. The method of claim 19, wherein the at least one nanostructure is grown from the catalyst metal layer.

21. The method of claim 15, wherein the nanostructure comprises a material selected from the group consisting of a IV group semiconductor, a III-V group semiconductor, a II-VI semiconductor, a IV-VI semiconductor, a IV-V-VI semiconductor, an oxide semiconductor, a nitride semiconductor, a metal and combinations thereof.

22. The method of claim 15, wherein the at least one nanostructure has at least one of a heterostructure in a radius direction and a heterostructure in a length direction.

23. The method of claim 22, wherein the at least one nanostructure comprises a material selected from the group consisting of a IV group semiconductor, a III-V group semiconductor, a II-VI semiconductor, a IV-VI semiconductor, a IV-V-VI semiconductor, an oxide semiconductor, a nitride semiconductor, a metal and combinations thereof.

24. The method of claim 22, wherein the at least one nanostructure is doped with a conductive impurity.
